(19) United States
(12) Patent Application Publication
(10) Pub. No.: US 2009/0227074 A1
(43) Pub. Date: Sep. 10, 2009

(54) METHOD OF MANUFACTURING DISPLAY DEVICE

(76) Inventors: Wang-Su HONG, Suwon-si (KR); Jeong-Ye CHOI, Yongin-si (KR)

Correspondence Address: Haynes and Boone, LLP;IP Section, 2323 Victory Avenue, SUITE 700, Dallas, TX, 75219, US

(21) Appl. No.: 12/347,912

(22) Filed: Dec. 31, 2008

(30) Foreign Application Priority Data
Mar. 4, 2008 (KR) 10-2008-0020088

(51) Int. Cl. H01L 21/77

(52) U.S. Cl. 438/149; 257/E21.002

(57) ABSTRACT

The present invention relates to a method for manufacturing a display device. In the method, a carrier substrate is prepared, a plastic substrate is formed on the carrier substrate, thin film transistors, pixel electrodes, and contact pads are formed on the plastic substrate, and a driver integrated circuit (IC) chip is mounted on the plastic substrate and electrically connected with the contact pads. Then, the plastic substrate is separated from the carrier substrate.

### CROSS-REFERENCE TO RELATED APPLICATION

This application claims the benefit of priority from Korean Patent Application No. 10-2008-0020088, filed in the Korean Intellectual Property Office on Mar. 4, 2008, the entire contents of which are incorporated herein by reference.

### BACKGROUND OF THE INVENTION

(a) Field of the Invention

The present invention relates to a method for manufacturing a display device.

(b) Description of the Related Art

Various types of display devices have been introduced to the market. Among these various types of display devices, the liquid crystal display (LCD) has been reduced in size and weight, and the performance thereof has been improved, due in large part to the rapid development of semiconductor technology. The liquid crystal display continues to receive attention as a most important type of display device.

Lately, there has arisen a strong demand for a flexible and compact display device.

Accordingly, a display device, with an improved level of integration, having a driver integrated circuit (IC) chip directly mounted on an edge portion of a substrate has been developed and has been used. Also, a flexible display device using a substrate made of plastic material has been developed.

However, there are many technical difficulties in mounting a driver IC chip directly on a substrate made of a plastic material. The driver IC chip is generally mounted directly on a substrate by means of an anisotropic conductive film (ACF).

When the driver IC chip is mounted directly on the substrate made of a plastic material, pads on the substrate, which are electrically connected to the driver IC chip, may be seriously cracked or damaged due to pressure and temperature that are generated while mounting the driver IC chip.

The above information disclosed in this background section is intended only for enhancement of understanding of the background of the invention and therefore it may contain information that is not part of the prior art.

### SUMMARY OF THE INVENTION

An exemplary embodiment of the present invention provides a method for manufacturing a display device. In the method, a carrier substrate is provided, and a plastic substrate is formed on the carrier substrate. A thin film transistor, a pixel electrode, and a contact pad are formed on the plastic substrate. A driver integrated circuit (IC) chip is mounted on the plastic substrate to be electrically connected with the contact pad, and the plastic substrate then is separated from the carrier substrate.

A sacrificial layer may be formed on the carrier substrate before the plastic substrate is formed.

The plastic substrate may be separated from the carrier substrate by removing the sacrificial layer.

Laser radiation may be applied to the sacrificial layer to remove the sacrificial layer.

The plastic substrate may be formed by coating a plastic material on the carrier substrate.

The plastic substrate may be separated from the carrier substrate by removing a part of the plastic substrate, the part of the plastic substrate being adjacent to the carrier substrate.

A part of the plastic substrate may be removed by applying laser radiation to the part of the plastic substrate.

The plastic substrate may be separated from the carrier substrate through a temperature difference generated by heating or cooling the plastic substrate and the carrier substrate.

The carrier substrate may be made of glass.

The plastic substrate may be made of a material including a polymer having excellent heat resistance, including one of polyimide (PI), polyamide (PA), polyethylene terephthalate (PET), fiber-reinforced polymers (FRP), polycarbonate, polyethersulfone (PES), polyarylate (PAR), and polyethylene naphthalate (PEN).

The mounting of a driving IC chip on the plastic substrate may include: forming an anisotropic conductive film (ACF) on the contact pad; disposing the driver IC chip on the anisotropic conductive film; and electrically connecting the contact pad to the driver IC chip by applying heat and pressure thereto.

### BRIEF DESCRIPTION OF THE DRAWINGS

FIG. 1 is a perspective view of a liquid crystal display device manufactured according to exemplary embodiments of the method of manufacture of the present invention.

FIG. 2 is a cross-sectional view of FIG. 1 taken along the line II-II.

FIGS. 3 to 6 are cross-sectional views sequentially illustrating a method for manufacturing a display device according to a first exemplary embodiment of the present invention.

FIG. 7 is a cross-sectional view illustrating a method for manufacturing a display device according to a second exemplary embodiment of the present invention.

### DESCRIPTION OF REFERENCE NUMERALS INDICATING PRIMARY ELEMENTS IN THE DRAWINGS

100: first display panel

101: thin film transistor

110: first substrate member

124: gate electrode

128: gate pad

130: gate insulating layer

140: semiconductor layer

165: source electrode

166: drain electrode

170: passivation layer

180: pixel electrode

185: contact pad

200: second display panel

210: second substrate member

220: light blocking member

230: color filter

250: overcoat layer

280: common electrode

300: liquid crystal layer

310: first alignment layer

320: second alignment layer

400: anisotropic conductive film

500: driver IC chip

### DETAILED DESCRIPTION OF THE EMBODIMENTS

The present invention is described more fully hereinafter with reference to the accompanying drawings, in which exemplary embodiments of the invention are shown. As those skilled in the art would understand, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

In the accompanying drawings, a display device having an amorphous silicon (a-Si) thin film transistor (TFT) formed through five mask processes is schematically shown as an exemplary embodiment of the present invention. A pixel denotes a minimum unit for displaying an image. However, a thin film transistor may be formed in various forms in the present invention and is not limited to those forms used in exemplary embodiments described in the specification.

To clearly explain the present invention, portions having no connection to the explanation are omitted, and the same or similar constituent elements are designated with the same reference numerals throughout the specification.

For various exemplary embodiments, constituent elements having the same constitution are designated with the same reference numerals and explained representatively in the first exemplary embodiment. In other exemplary embodiments, only constituent elements that are different from those in the first exemplary embodiment are described.

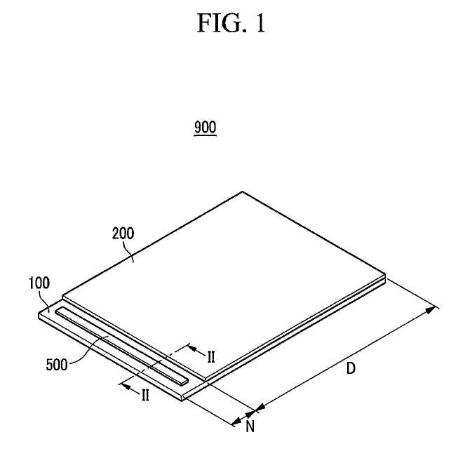

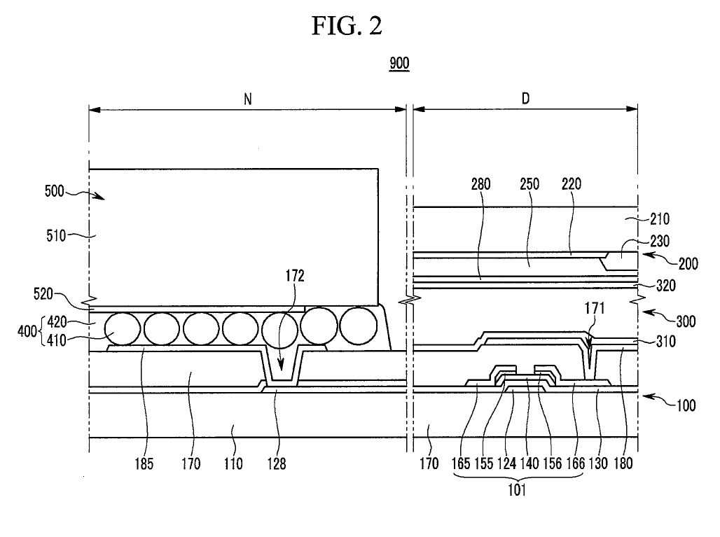

A display device manufactured according to exemplary embodiments of the present invention will be described with reference to FIG. 1 and FIG. 2.

As shown in FIG. 1, a display device 900 includes a first display panel 100, a second display panel 200, a liquid crystal layer 300 (shown in FIG. 2), and a driver integrated circuit (IC) chip 500. The second display panel 200 has a smaller surface area than that of the first display panel 100. An overlapping region of the first display panel 100 and the second display panel 200 is referred to as a display area D. An area of the first display panel 100, which is not overlapped by the second display panel, is referred to as a non-display area N. The driver IC chip 500 is directly mounted on the first display panel 100 in the non-display area N.

With reference to FIG. 2, the structure of the display device 900 is described in terms of sequentially formed layers.

First, a structure of the first display panel 100 is described.

The first display panel 100 includes a plastic substrate 110 that is made of a material including a polymer having excellent heat resistance, such as polyimide (PI), polyamide (PA), polyethylene terephthalate (PET), fiber-reinforced polymers (FRP), polycarbonate, polyethersulfone (PES), polyarylate (PAR), and polyethylene naphthalate (PEN). However, the material of the plastic substrate 110 is not limited to these polymers. Any other material may be used if the material has excellent heat resistance to allow thin film processes to be performed on the plastic substrate 110. Hereinafter, the plastic substrate 110 may be referred to as a first substrate member.

A gate wiring pattern having a plurality of gate electrodes 124 is formed on the first substrate member 110. Although not shown, the gate wiring pattern may further include a plurality of gate lines connected to the gate electrodes 124, and a plurality of first storage electrode lines. The gate wiring pattern further includes gate pads 128, formed in the non-display area N, and connected to the gate lines.

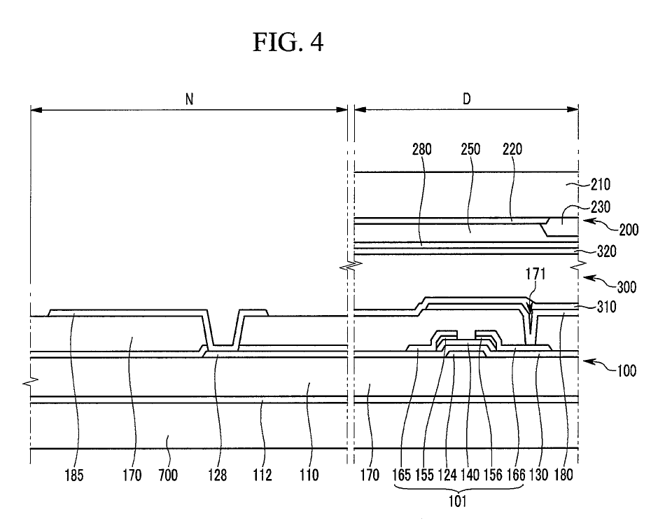

The gate wiring pattern, including the gate electrodes 124 and the gate pads 128, is formed in a gate level conductive layer which may include a metal such as Al, Ag, Cr, Ti, Ta, Mo, or alloys thereof. Although the gate level conductive layer is shown as a single layer in FIG. 4, the gate level conductive layer may include multiple layers, for example, a metal layer made of Cr, Mo, Ti, Ta, or alloys thereof, which have excellent physicochemical characteristics, and a layer that includes an Al series or Ag series metal having low resistivity. In addition to these metals, the gate level conductive layer may be made of various other metals or conductors. It is preferable, when the gate level conductive layer includes multiple layers, that etch patterning be performed under the same etch conditions for each of the multiple layers.

A gate insulating layer 130 is formed on the gate wiring pattern and on the first substrate member 110. The gate insulating layer 130 may be made of silicon nitride (SiNx), for example.

A semiconductor layer 140 is formed on the gate insulation layer 130 at predetermined regions above the gate electrodes 124. The semiconductor layer includes a semiconductor such as silicon and may be amorphous silicon. Ohmic contacts 155 and 156 are formed on the semiconductor layer 140. The ohmic contacts may include a metal silicide or heavily doped N-type silicon.

A data wiring pattern is formed in a data level conductive layer deposited on the gate insulating layer 130 and on the semiconductor layer 140. The data wiring pattern includes a plurality of source electrodes 165 each source electrode 165 having a region that overlaps an ohmic contact 155 which overlaps a portion of a gate electrode 124, and a plurality of drain electrodes 166 separated from the source electrodes 165, each drain electrode 166 having a region that overlaps an ohmic contact 156 which overlaps a portion of a gate electrode 124. Although not shown, the data wiring pattern may further include a plurality of data lines that cross the gate lines, a plurality of second storage electrode lines overlapping first storage electrodes, and data pads formed on the non-display area N and connected to the data lines.

Like the gate level conductive layer, the data level conductive layer is made of a conductive material such as chromium, molybdenum, aluminum, or alloys thereof, and may be formed as a single layer or as multiple layers.

Each semiconductor layer 140 includes a region which overlaps the gate electrode 124, a region which is overlapped by the source electrode 165, and a region which is overlapped by the drain electrode 166. The gate electrode 124, the source electrode 165, and the drain electrode 166 become three electrodes of a thin film transistor 101. The semiconductor layer 140 between the source electrode 165 and the drain electrode 166 becomes a channel region of the thin film transistor 101. The structure of the thin film transistor 101 is not limited to the structure shown in FIG. 2. The thin film transistor 101 may have various well-known structures within a range that allows those skilled in the art to easily modify it.

Ohmic contacts 155 and 156 are formed between the semiconductor layer 140 and the source electrode 165 and the drain electrode 166, respectively, to reduce contact resistance therebetween. The ohmic contacts 155 and 156 are made of silicide or amorphous silicon doped with an n-type impurity at a high concentration.

A passivation layer 170 is deposited on the data wiring pattern and on the gate insulating layer. The passivation layer 170 is formed by plasma enhanced chemical vapor deposition (PECVD) and is made of a low dielectric constant insulating material such as a-Si:C:O or a-Si:O:F, an inorganic insulating material such as silicon nitride or silicon oxide, or, alternatively, an organic insulating material.

A plurality of pixel electrodes 180 and a plurality of contact pads 185 are formed on the passivation layer 170. The pixel electrodes 180 and the contact pads 185 may be made of a transparent conductor such as indium tin oxide (ITO) or indium zinc oxide (IZO), or, alternatively, may be made of an opaque conductor such as aluminum (Al).

The passivation layer 170 includes a plurality of first contact holes 171 for exposing portions of the drain electrodes 166 and second contact holes 172 for exposing portions of the gate pads 128 and data pads (not shown). The pixel electrodes 180 are electrically connected to the drain electrodes 166 through the first contact holes 171. Also, the contact pads 185 are electrically connected to the gate pads 128 and the data pads (not shown) through the second contact holes 172.

Second, a structure of the second display panel 200 is described.

The second display panel 200 includes a second substrate member 210. Like the first substrate member 110, the second substrate member 210 may be made of a plastic material. However, the second substrate member 210 is not limited to a plastic material. The second substrate member 210 may be formed of various insulating materials such as glass, quartz, or ceramic. However, if the second substrate member 210 is made of a flexible material as well as the first substrate member 110, the practical use range of the display device 900 may be expanded, thereby further improving the overall utility of the display device 900. Therefore, it is preferable that the second substrate member 210 be a plastic substrate as well as the first substrate member 110.

A light blocking member 220 is formed on the second substrate member 210. The light blocking member 220 includes openings facing the pixel electrodes 180 of the first display panel 100, and blocks light from leaking through a gap between adjacent pixels. Here, a pixel is a minimum unit used for displaying an image. The light blocking member 220 is also formed at locations corresponding to the thin film transistors 101 in order to block external light from entering the semiconductor layers 140 of the thin film transistors 101.

In order to block light, the light blocking member 220 may be made of a photosensitive organic material having an opaque pigment, or may include a metal layer. The opaque pigment may be carbon black or titanium oxide.

Color filters 230 having three primary colors are sequentially disposed on the second substrate member 210 in the openings formed in the light blocking member 220. Here, colors of the color filters 230 are not limited to three primary colors. The color filters 230 may be variously constituted with at least one primary color. Although a boundary of each color filter 230 is located on the light blocking member 220, the present invention is not limited thereto. Edges of adjacent color filters 230 may be overlapped with each other to block leaked light like the light blocking member 220. In the latter configuration, the light blocking member 220 disposed along the boundaries of pixels may be omitted.

An overcoat layer 250 is formed on the light blocking member 220 and the color filters 230. Such an overcoat layer 250 may be omitted. The overcoat layer 250 protects the color filters 230 and smoothes the surface thereof.

A common electrode 280 is formed on the overcoat layer 250. An electric field is formed between the common electrode and the pixel electrode 180. The common electrode 280 is made of a transparent conductor such as ITO or IZO.

The structures of the first display panel 100 and the second display panel 200 are not limited to the above-described structures and are not limited to the structures shown in the accompanying drawings. The first display panel 100 and the second display panel 200 may have various well-known structures within a range that allows those skilled in the art to modify them. For example, the color filter may be formed on the first display panel instead of the second display panel.

The liquid crystal layer 300 includes a plurality of liquid crystal molecules, and is disposed between the first display panel 100 and the second display panel 200. The liquid crystal layer 300 may include various types of liquid crystal molecules according to a driving method of the display device 900, such as vertically aligned liquid crystal molecules, horizontally aligned liquid crystal molecules, and blue-phase liquid crystal molecules.

Also, the display device 900 further includes a first alignment layer 310 formed on the pixel electrode 180 and a second alignment layer 320 formed on the common electrode 280. The first alignment layer 310 and the second alignment layer 320 align liquid crystal molecules of the liquid crystal layer 300.

The driver IC chip 500 is directly mounted on the first display panel 100, and is electrically connected to the contact pads 185. Here, the driver IC chip 500 and the contact pads 185 are electrically connected to each other through an anisotropic conductive film (ACF) 400. The driver IC chip 500 includes a main body 510 and terminals 520. The anisotropic conductive film (ACF) 400 includes an adhesive layer 420 and conductive balls 410 disposed in the adhesive layer 420. The contact pads 185 on the first display panel 100 are electrically connected to the terminals 520 of the driver IC chip 500 through the conductive balls 410 of the anisotropic conductive film (ACF) 400.

As described above, the level of integration of the display device 900 may be increased while the flexibility of a plastic substrate is sustained by directly mounting the driver IC chip 500 on the first substrate member 110 which is a plastic substrate.

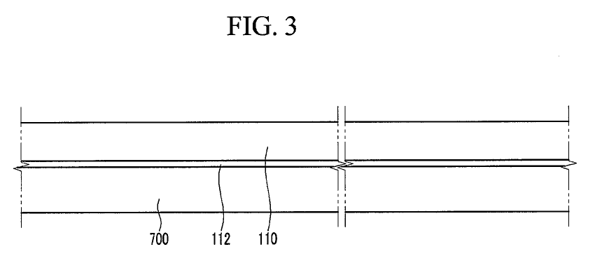

Hereinafter, a method for manufacturing a display device according to a first exemplary embodiment of the present invention is described with reference to FIG. 3 to FIG. 6.

First, as shown in FIG. 3, a carrier substrate 700 made of generally-used glass is provide and prepared. Preparation of the carrier substrate 700 may include cleaning the carrier substrate 700. A sacrificial layer 112 is formed on the carrier substrate 700. The plastic substrate 110 is formed on the sacrificial layer 112 by coating a plastic material on to the sacrificial layer 112.

The plastic substrate 110 is made of material including a polymer having excellent heat resistance, such as polyimide (PI), polyamide (PA), polyethylene terephthalate (PET), fiber-reinforced polymers (FRP), polycarbonate, polyethersulfone (PES), polyarylate (PAR), and polyethylene naphthalate (PEN). The material of the plastic substrate 110 is not limited to these polymers. Any other material may be used if the material has excellent heat resistance sufficient to allow thin film processes to be performed on the plastic substrate 110. Hereinafter, the plastic substrate 110 may be referred to as the first substrate member. The sacrificial layer 112 and the first substrate member 110 are formed on the carrier substrate 700 by doubly coating a polymer material on the carrier substrate 700. Here, the first substrate member 110 and the sacrificial layer 112 are substantially made of similar materials. However, the first substrate member 110 and the sacrificial layer 112 are formed to react differently to laser light or to a high temperature.

As shown in FIG. 4, the first display panel 100 is completed by providing the elements of the first display panel shown in FIG. 2 on the plastic substrate 110. Here, the thin film transistors 101 and the pixel electrodes 180 are formed in a display area D, and the contact pads 185 are formed in a non-display area N. Also, the second display panel 200 is independently manufactured and is disposed opposite and facing the first display panel 100. A liquid crystal layer 300 is disposed between the first display panel 100 and the second display panel 200.

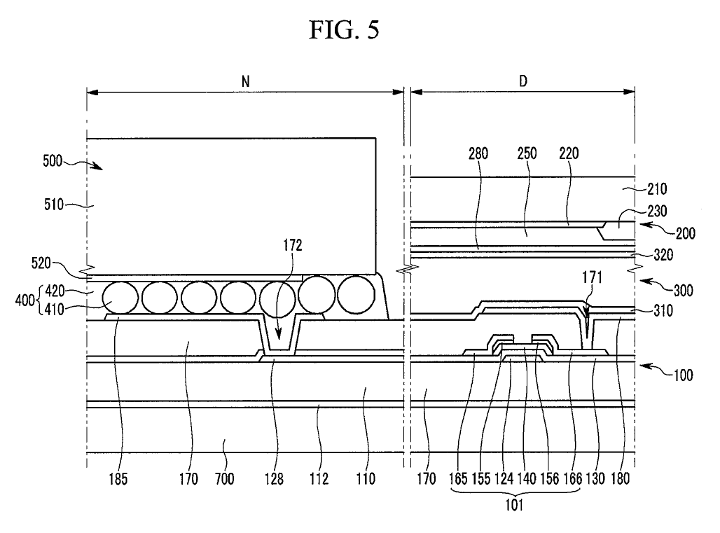

As shown in FIG. 5, a driver IC chip 500 is directly mounted on the first display panel 100 including the first substrate member 110 which is a plastic substrate to electrically connect the driver IC chip 500 with the contact pads 185. Here, an anisotropic conductive film (ACF) 400 is used. That is, the anisotropic conductive film 400 electrically connects the terminals 520 of the driver IC chip 500 to the contact pads 185. That is, in the method for connecting the contact pads 185 to the driver IC chip 500 using the anisotropic conductive film 400, the anisotropic conductive film 400 is formed on the contact pads 185, and the driver IC chip 500 is disposed on the anisotropic conductive film 400. Then, the contact pads 185 and the driver IC chip 500 are electrically connected to each other by applying heat and pressure.

High temperature and pressure are applied to the first substrate member 110 while mounting the driver IC chip 500 on the first substrate member 110 using the anisotropic conductive film 400 in order to electrically connect the driver IC chip 500 and the contact pads 185. Since the first substrate member 110 is a plastic substrate, the first substrate member 110 is fragile at such applied high temperature and pressure. Therefore, the contact pads 185 formed on the first substrate member 110 may be damaged while mounting the driver IC chip 500.

However, the weakness of the first substrate member 100 at elevated temperature and pressure is compensated by supporting the first substrate member 110 which is a plastic substrate on the carrier substrate 700 made of glass or other suitable material.

Therefore, in accordance with the method of the present invention the driver IC chip 500 is stably mounted on the first substrate member 110 which is a plastic substrate.

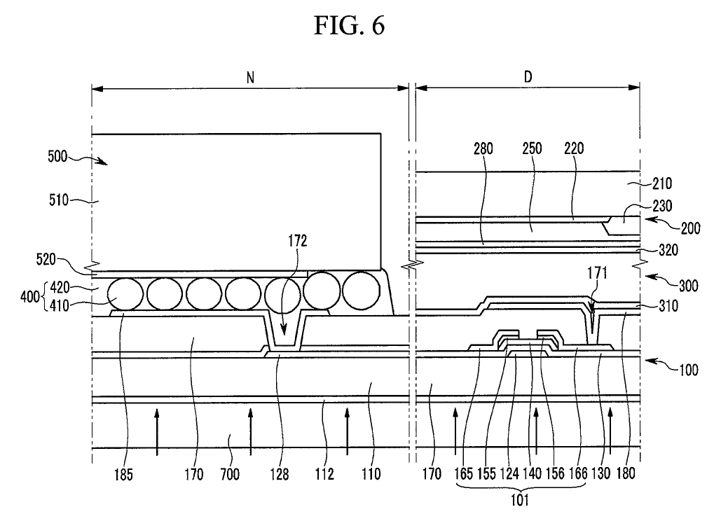

Then, as shown in FIG. 6, the sacrificial layer 112 is removed by applying radiation from a laser onto the sacrificial layer 112 through the carrier substrate 700. That is, the first substrate member 110 is separated from the carrier substrate 700 by removing the sacrificial layer 112. The application of the laser radiation to the sacrificial layer 112 is indicated in FIG. 6 by the vertical arrows.

In FIG. 2, the completed display device 900 including the first display panel 100 with the driver IC chip 500 stably mounted on the first substrate member 110 which is a plastic substrate, the second display panel 200, and the liquid crystal layer 300, is shown after the carrier substrate 700 has been separated from the first display panel.

As described above, the driver IC chip 500 can be stably mounted on the first substrate member 110, which is a plastic substrate, based on the manufacturing method according to the first exemplary embodiment of the present invention. Therefore, a display device in which a driver IC chip is mounted on a flexible plastic substrate can be manufactured while sustaining the flexibility thereof.

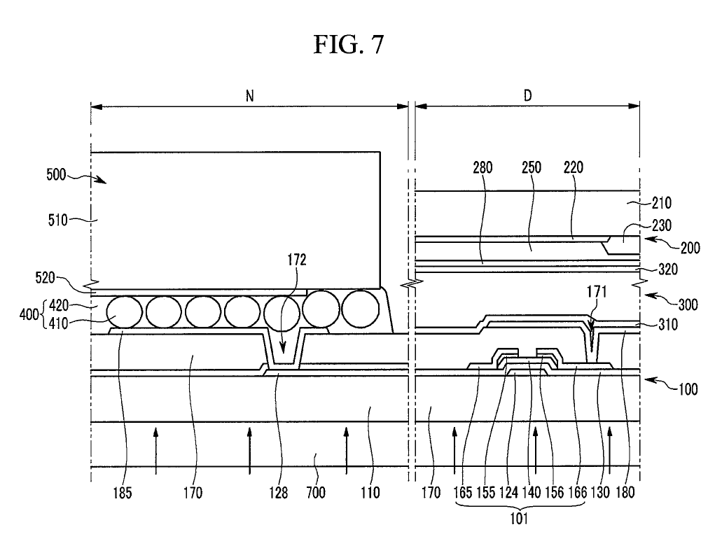

A method for manufacturing a display device according to a second exemplary embodiment of the present invention is described with reference to FIG. 7.

First, a carrier substrate 700 made of a generally-used glass substrate is provided and prepared. Then, a plastic substrate 110 is formed on the carrier substrate 700 by coating a plastic material on the carrier substrate 700. Here, the plastic substrate 110 is referred to as a first substrate member. The first substrate member 110 is formed without a sacrificial layer.

Then, a first display panel 100 is manufactured by forming the elements shown in FIG. 2, or equivalent elements, on the first substrate member 110. Also, a second display panel 200 is independently manufactured and disposed opposite the first display panel 100 to face each other. In this process, a liquid crystal layer 300 may be disposed between the first display panel 100 and the second display panel 200.

Then, a driver IC chip 500 is directly mounted on the first substrate member 110 using an anisotropic conductive film 400 to electrically connect the driver IC chip 500 and the contact pads 185.

As indicated by the vertical arrows in FIG. 7, laser radiation is applied through the carrier substrate 700 to the first substrate member 110 that is a plastic substrate. This application of the laser radiation to the first substrate member 110 causes the first substrate member 110 to separate from the carrier substrate 700. A thin portion of the first substrate member may be eliminated by the laser light. As described above, the first substrate member 110 is separated from the carrier substrate 700 and the process of separation may include removing a part of the first substrate member 110.

As shown in FIG. 2, a display device 900 having the driving IC chip 500 directly mounted on the first display panel 100 including the first substrate member 110 made of the plastic substrate is manufactured.

Using the manufacturing method according to the second embodiment, the driver IC chip 500 can be stably attached to a first display panel 100 that includes the first substrate member 110 made of the plastic substrate. Therefore, a more integrated and flexible display device can be manufactured.

The present invention is not limited to the method including a step of using a laser. Alternatively the first substrate member 110 may be separated from the carrier substrate 700 through a temperature difference generated by heating or cooling the first substrate member 110 made of the plastic substrate and the carrier substrate 700.

Since the methods for separating substrates by heating or cooling the substrates are well known to those skilled in the art, a detail description thereof is omitted.

Embodiments of the present invention provide a display device having a driver IC chip stably mounted on a flexible plastic substrate.

Also, embodiments of the present invention provide a method for manufacturing a display device having a driver IC chip stably mounted on a flexible plastic substrate.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for manufacturing a display device, comprising:
providing a carrier substrate;
forming a plastic substrate on the carrier substrate;
forming a thin film transistor, a pixel electrode, and a contact pad on the plastic substrate;
mounting a driver integrated circuit (IC) chip on the plastic substrate, the driver integrated circuit being electrically connected with the contact pad; and
separating the plastic substrate from the carrier substrate.

2. The method of claim 1, further comprising forming a sacrificial layer on the carrier substrate before forming the plastic substrate.

3. The method of claim 2, wherein separating the plastic substrate from the carrier substrate includes removing the sacrificial layer.

4. The method of claim 3, wherein removing the sacrificial layer includes applying laser radiation to the sacrificial layer to remove the sacrificial layer.

5. The method of claim 1, wherein forming the plastic substrate includes coating a plastic material onto the carrier substrate.

6. The method of claim 5, wherein separating the plastic substrate from the carrier substrate includes removing a part of the plastic substrate, which is adjacent to the carrier substrate.

7. The method of claim 6, wherein removing the part of the plastic substrate includes applying laser radiation to the part of the plastic substrate.

8. The method of claim 1, wherein separating the plastic substrate from the carrier substrate includes heating or cooling the plastic substrate and the carrier substrate.

9. The method of claim 1, wherein the carrier substrate comprises glass.

10. The method of claim 1, wherein the plastic substrate comprises a material comprising a polymer having excellent heat resistance, which is one of polyimide (PI), polyamide (PA), polyethylene terephthalate (PET), fiber-reinforced polymers (FRP), polycarbonate, polyethersulfone (PES), polyarylate (PAR), and polyethylene naphthalate (PEN).

11. The method of claim 1, wherein mounting a driving IC chip on the plastic substrate comprises:
forming an anisotropic conductive film (ACF) on the contact pad;
disposing the driver IC chip on the anisotropic conductive film; and
electrically connecting the contact pad to the driver IC chip by applying heat and pressure.
